(19) United States
(12) Patent Application Publication
(10) Pub. No.: US 2009/0278126 A1
(43) Pub. Date: Nov. 12, 2009

(54) METAL LINE SUBSTRATE, THIN FILM TRANSISTOR SUBSTRATE AND METHOD OF FORMING THE SAME

(75) Inventors: Dong-Ju YANG, Seoul (KR); Sang-Gab KIM, Seoul (KR); Ki-Yeup LEE, Seoul (KR); Yun-Jong YEO, Seoul (KR); Shin-Il CHOI, Seoul (KR); Hong-Kee CHIN, Suwon-si (KR); Yu-Gwang JEONG, Yongin-si (KR); Seung-Ha CHOI, Siheung-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si, (KR)

(21) Appl. No.: 12/431,969

(22) Filed: Apr. 29, 2009

(30) Foreign Application Priority Data
May 6, 2008 (KR) 1020080041934

(51) Int. Cl. H01L 29/786; H01L 23/522; H01L 21/768

(52) U.S. Cl. 257/57; 257/741; 438/674; 257/E23.142; 257/E21.575; 257/E29.289

(57) ABSTRACT

A metal line substrate and a method of fabricating thereof, the metal line substrate including an insulating layer and a capping layer disposed on an insulating substrate, a trench defined by the insulating layer and the capping layer disposed on the insulating substrate, a seed layer pattern disposed on the insulating substrate, and a low-resistive conductive layer pattern disposed in the trench and contacting the seed layer pattern. The capping layer pattern includes a protrusion region which is in contact with the low-resistive conductive layer pattern.

This application claims priority to Korean Patent Application No. 10-2008-0041934, filed on May 6, 2008, and all the benefits accruing therefrom under 35 U.S.C. §119, the disclosure of which is hereby incorporated herein by reference in its entirety for all purposes.

### BACKGROUND OF THE INVENTION

(a) Field of the Invention

The present invention relates to a metal line substrate and a thin film transistor substrate, and more particularly, to a buried type of metal line substrate and thin film transistor, and a method of forming the same.

(b) Description of the Related Art

Liquid crystal display (“LCD”) devices, which are one of the most widely used flat panel display devices, include two substrates having a plurality of electrodes and a liquid crystal layer interposed between the two substrates. LCD devices display images by adjusting the amount of light transmitted therethrough by applying a voltage to the plurality of electrodes so that liquid crystal molecules of the liquid crystal layer can be rearranged.

In order to meet the ever-increasing demand for large screens and high resolution displays, the resistance of data lines and/or gate lines should be lower than those of small screens or low resolution displays. To fabricate a low resistance gate lines and data lines, they should be formed of a low-resistive conductive material including copper or silver or they should be a wide or thick metal line, so that a data signal and a gate signal applied to a pixel electrode or a switching elements on a TFT substrate can be adequately transmitted to all pixel electrodes or switching elements that are connected to the data lines and gate lines, regardless of the their length. A method for the formation of the thick metal line on the substrate using a trench formation and an electroless plating method (“ELP”) may be used in the manufacturing of an LCD device.

### BRIEF SUMMARY OF THE INVENTION

Since low resistance gate lines and data lines may be formed of a low-resistive conductive material including copper or silver, or may be formed in a relatively wide or relatively thick metal line, there are technical challenges in manufacturing an LCD device including these low resistance gate lines and data lines. For example, if the width of the metal line is increased to decrease the metal line resistance, the transmittance of the LCD devices is decreased because the areas of the pixel regions for transmitting light are decreased. Meanwhile, if the thickness of the metal line is increased to decrease the metal line resistance, the image quality of LCD devices are deteriorated because the liquid crystal (“LC”) molecules near the thick metal lines can not be controlled due to increased differences of height between the metal lines and substrate.

Additionally, if a method for the formation of the thick metal line on the substrate uses a trench formation and/or an electroless plating method (“ELP”), the relatively thick metal line formed by ELP in the trench may deteriorate the adhesion property of the metal lines to the substrate or cause defects by interacting with other layers.

Exemplary embodiments of the present invention provide a buried type of metal line which has an increased adhesive strength with a bottom surface, and a method of forming the same.

Exemplary embodiment of the present invention also provide thin film transistor (“TFT”) substrates including a buried type of metal line, which has an increased adhesive strength with a bottom surface, and a method of forming the same.

Additional features of the invention will be set forth in the description which follows, and in part will be apparent from the description, or may be learned by practice of the invention.

An exemplary embodiment of the present invention discloses a metal line. The metal line includes an insulating substrate, an insulating layer pattern and a capping layer pattern disposed on the insulating substrate, a seed layer pattern disposed on the insulating substrate, a low-resistive conductive layer pattern disposed on the seed layer pattern. The capping layer pattern disposed on the insulating layer pattern includes a protrusion region formed at least on part of the low-resistive conductive layer pattern. The low-resistive conductive layer pattern has a same or lower surface heights in comparison with the height of the capping layer pattern. The length of the protrusion region is longer than 0.5 micrometer (μm). The width of the capping layer pattern is wider than 0.5 micrometer (μm). The capping layer includes at least one of SiOx, SiNx and SiONx layer. The thickness of the capping layer is about 100 Å to about 5,000 Å. The thickness of the insulating layer is about 5,000 Å to about 50,000 Å. The metal line includes at least one of a copper and a copper alloy. The metal line may be directly in contact with both the insulating substrate and the seed layer pattern. The seed layer pattern includes at least one of a molybdenum (Mo), a copper (Cu), an aluminum (Al), a gold (Au), a silver (Ag), a titanium (Ti), an oxygen (O), a nitrogen (N) and an alloy thereof. The thickness of the seed layer pattern is about 100 Å to about 5,000 Å.

An exemplary embodiment discloses a thin film transistor (“TFT”) substrate. The TFT substrate includes an insulating substrate, and a gate line and a data line disposed on the insulating substrate. The data line or the gate line is disposed in a trench which includes an insulating layer pattern and a capping layer pattern formed on the insulating substrate. The TFT substrate also includes a seed layer pattern disposed on the insulating substrate, the gate or data line formed on the seed layer pattern, and the capping layer pattern is formed on the insulating layer. The capping layer pattern includes a protrusion region formed at least on part of the gate and/or data line.

An exemplary embodiment discloses a method of fabricating a metal line. The method includes forming a metal line on an insulating substrate. The method includes forming a seed layer pattern on the insulating substrate, forming an insulating layer pattern and a capping layer pattern on the insulating substrate, and forming a low-resistive conductive layer pattern on the seed layer pattern, such as by an electroless plating method. The capping layer pattern includes a protrusion region formed at least on part of the low-resistive conductive layer pattern.

An exemplary embodiment discloses a method of fabricating a thin film transistor (“TFT”) substrate. The method includes forming a gate line and a data line on an insulating substrate, such as by an electroless plating method, forming an insulating layer pattern and a capping layer pattern on the insulating substrate, and forming a seed layer pattern on the insulating substrate. The capping layer pattern on the insulating layer pattern includes a protrusion region formed at least on part of the gate and/or data line.

An exemplary embodiment discloses a method of fabricating a metal line on an insulating substrate. The method includes forming an insulating layer and a capping layer on the insulating substrate, forming a photoresist layer pattern on the capping layer, etching the capping layer and the insulating layer to form an insulating layer pattern and a capping layer pattern, depositing a seed layer on the photoresist layer pattern, removing the seed layer on the photoresist layer pattern from the TFT substrate, such as by a lift-off method, to form a seed layer pattern, and forming a low-resistive conductive layer pattern on the seed layer pattern, such as by an electroless plating method. The capping layer pattern includes a protrusion region formed at least on part of the low-resistive conductive layer pattern.

An exemplary embodiment discloses a method of fabricating a metal line on an insulating substrate. The method includes forming a seed layer pattern on the insulating substrate, forming an insulating layer and a capping layer on the insulating substrate, forming a negative photoresist layer on the capping layer, exposing a light from a back side of the insulating substrate and forming a negative photoresist layer pattern, forming the negative photoresist layer pattern on the capping layer, forming an insulating layer pattern and a capping layer pattern, and forming a low-resistive conductive layer pattern on the seed layer pattern, such as by an electroless plating method. The capping layer pattern includes a protrusion region formed at least on part of the low-resistive conductive layer pattern and a width of the capping layer pattern is smaller than that of the insulating layer pattern.

It is to be understood that both the foregoing general description and the following detailed description are exemplary and explanatory and are intended to provide further explanation of the invention as claimed.

### BRIEF DESCRIPTION OF THE DRAWINGS

The above and/or other aspects and advantages of the present invention will become apparent and more readily appreciated from the following description of the embodiments, taken in conjunction with the accompanying drawings of which,

FIG. 1 is a cross-sectional view of an exemplary embodiment of a metal line obtained using a method of fabricating the metal line according to the present invention.

FIG. 2, FIG. 3, FIGS. 4A and 4B, and FIG. 5 are cross-sectional views for explaining an exemplary embodiment of the method of fabricating the metal line according to the present invention.

FIG. 6 is a cross-sectional view of the metal line in FIGS. 1-5 according to the present invention.

FIG. 7 is plan view of an exemplary embodiment of a thin film transistor (“TFT”) liquid crystal display (“LCD”) panel according to the present invention.

FIG. 8 is a cross-sectional view of the TFT LCD panel according to an exemplary embodiment of the present invention which is shown along the line from I to I′.

FIG. 9 is a cross-sectional view of the TFT LCD panel according to an exemplary embodiment of the present invention which is shown along the line from II to II′.

FIG. 10 is a cross-sectional view of another exemplary embodiment of a metal line obtained using a method of fabrication metal line according to the present invention.

FIG. 11, FIG. 12, FIG. 13 and FIG. 14 are cross-sectional views for explaining another exemplary embodiment of a method of forming the metal line according to the present invention.

FIG. 15 and FIG. 16 are a cross-sectional view for explaining other exemplary embodiments of a method of fabricating the metal line according to the present invention.

### DETAILED DESCRIPTION OF THE INVENTION

The invention will be described more fully hereinafter with reference to the accompanying drawings, in which exemplary embodiments of the present invention are illustrated. The invention may, however, be embodied in different forms and should not be construed as limited to the embodiments set forth herein. Rather, these embodiments are provided so that this disclosure will be thorough and complete, and will fully convey the scope of the present invention to those skilled in the art.

In the figures, the dimensions of layers and regions may be exaggerated for clarity of illustration. It will also be understood that when a layer or element is referred to as being “on” another layer or element, it can be directly on the other layer or element, or intervening layers may also be present. Further, it will be understood that when a layer is referred to as being “under” another layer or element, it can be directly under, and one or more intervening layers or elements may also be present. In addition, it will also be understood that when a layer or an element is referred to as being “between” two layers or elements, it can be the only layer between the two layers or elements, or one or more intervening layers or elements may also be present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that the order in which each fabrication method disclosed in this disclosure are performed is not restricted to those set forth herein, unless specifically mentioned otherwise. Accordingly, the order in which each fabrication method disclosed in this disclosure is performed can be varied within the scope of the present invention, and the resulting consequences that are obvious to one of ordinary skill in the art to which the present invention pertains will be regarded as being within the scope of the present invention.

Hereinafter, the present invention will be described in detail with reference to the accompanying drawings.

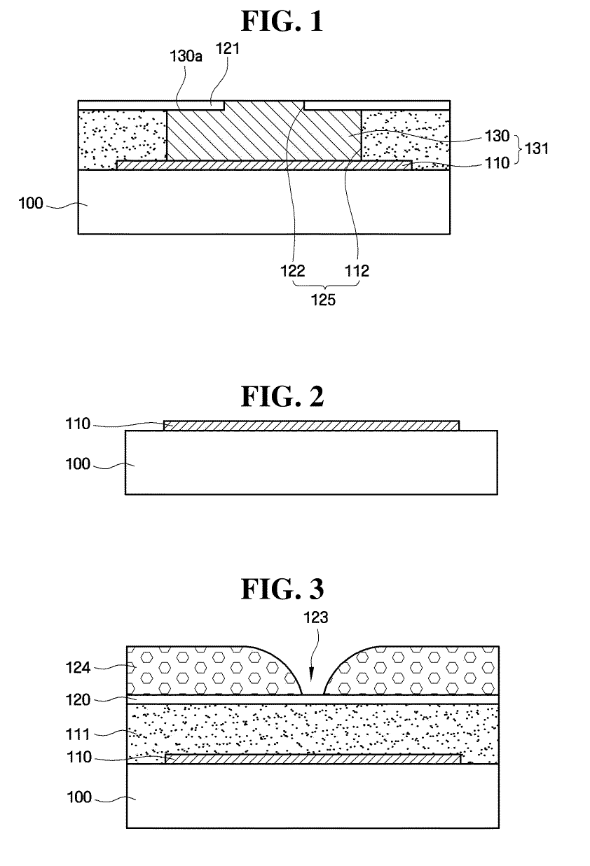

FIG. 1 is a cross-sectional view of an exemplary embodiment of a metal line obtained using a method according to the present invention.

Referring to FIG. 1, a seed layer pattern 110 is disposed on an insulating substrate 100. An insulating layer pattern 112 and a capping layer pattern 122 are disposed on the seed layer pattern 110. The capping layer pattern 122 further includes a protrusion region 121, and may be referred to as a “stepped” portion of the capping layer 120. A trench 125 includes the insulating layer pattern 112 and the capping layer pattern 122. The trench 125 is filled with a low-resistive conductive layer pattern 130, which is disposed on the seed layer pattern 110, In one exemplary embodiment, the low-resistive conductive layer pattern 130 is disposed on the seed layer pattern 110 by an electroless plating method. The low-resistive conductive layer 130 contacts a bottom side of the protrusion region 121. The trench 125 may be referred to as being solely defined collectively by an upper surface of the seed layer pattern 110, inner surfaces of the insulating pattern 112, inner surfaces of the capping layer pattern 122 and a plane that is coextensive with an upper surface of the capping layer pattern 122.

The low-resistive conductive layer pattern 130 disposed on the seed layer pattern 110 by the electroless plating method has a relatively low adhesive strength with other surfaces. Consequently, the low-resistive conductive layer pattern 130 may separate from the seed layer pattern 110 and/or the substrate 100. However, in the illustrated embodiment, the adhesive strength between the low-resistive conductive layer pattern 130 and the seed layer pattern 110 is increased because of the presence of the protrusion region 121 of the capping layer pattern 122 suppressing the top surface 130a of the low-resistive conductive layer pattern 130. Since the adhesive strength of the low-resistive conductive layer pattern 130 is increased, the low-resistive conductive layer pattern 130 is properly adheres to and is disposed on the seed layer 110 and/or the insulating substrate 100. A metal line 131 may include the low-resistive conductive layer pattern 130 and the seed layer pattern 110, as illustrated in FIG. 1.

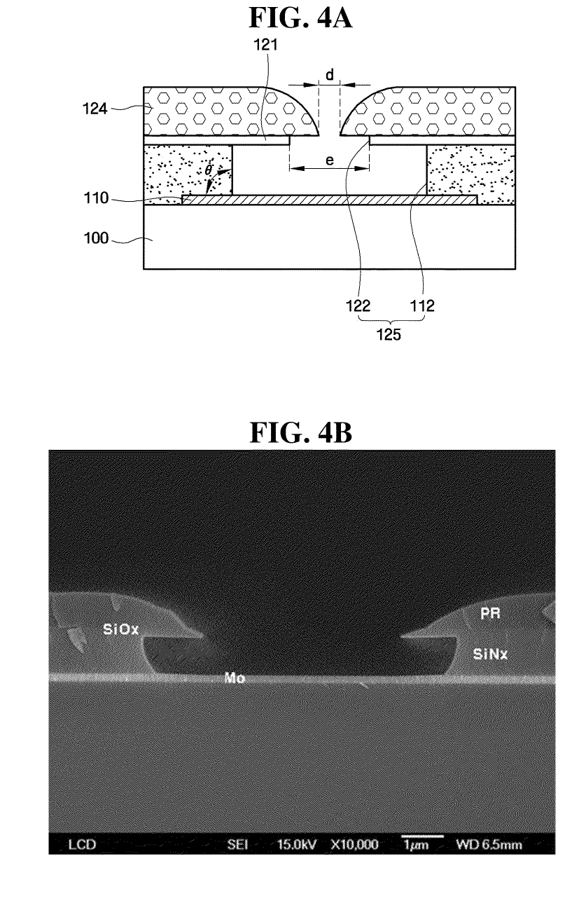

An exemplary embodiment of a method of fabricating a metal line 131 according to the present invention will be described below in detail with reference to FIG. 2, FIG. 3, FIGS. 4A and 4B, and FIG. 5, which are cross-sectional views for explaining the method.

Referring to FIG. 2, a seed layer pattern 110 is formed on an insulating substrate 100. A seed layer (not shown) is formed on the insulating substrate 100, which may be made of an inorganic material such as glass or quartz, or an organic material such as polymer resin. The seed layer may be formed of molybdenum (Mo), aluminum (Al), chromium (Cr), nickel (Ni), copper (Cu), titanium (Ti), tantalum (Ta), and tungsten (W) or an alloy of any of these materials. In preferred exemplary embodiments, the seed layer may be formed of molybdenum (Mo) or molybdenum nitride (MoN), which may have excellent adhesion capability to upper layers of the TFT LCD panel. In one exemplary embodiment, the seed layer may be formed to a thickness of about 100 Å to about 5,000 Å, such as by using a sputtering method.

In an alternative embodiment, a photoresist layer (not shown) may be formed on the seed layer. The photoresist layer may be selectively exposed using an optical mask (not shown). The photoresist layer, which has photochemical properties that are changed by the exposure, is developed, thereby obtaining a photoresist layer pattern (not shown) having a desired shape.

The seed layer pattern 110 may be formed by etching the seed layer using the photoresist layer pattern as an etching mask. The seed layer pattern 110 may be part of a gate electrode of a TFT. A gate pad seed layer pattern (not shown), which may transmit signals received from an external source, may be formed at one end of the seed layer pattern. The photoresist layer pattern located on the seed layer pattern may then be removed using, for example, a stripper.

Referring to FIG. 3 and FIG. 4A, at least one of an insulating layer 111 and a capping layer 120 is formed on the seed layer pattern 110. In exemplary embodiments, the insulating layer 111 and/or the capping layer 120 may be deposited by a chemical vapor deposition method. The insulating layer 111 and/or the capping layer 120 may include at least one of SiOx, SiNx and SiONx layer, but are not limited thereto. The insulating layer 111 and/or the capping layer 120 may also include organic materials, such as polymer resin.

A photoresist layer 124 may be formed on the insulating layer 111. The photoresist layer 124 may be selectively exposed using an optical mask (not shown). The photoresist layer 124 is developed, thereby obtaining a photoresist layer pattern 123 having a desired shape, as previously described.

The insulating layer 111 and the capping layer 120 are etched using the photoresist layer pattern 123 as an etching mask. An etching rate of the insulating layer 111 and the capping layer 120 can be controlled by manipulating etching conditions. In exemplary embodiments, the etching may be performed by a wet chemical etching method or a dry etching method. The etching rate of the insulating layer 111 is preferably faster than that of the capping layer 120. In one exemplary embodiment, the insulating layer 111 may be SiNx, and the capping layer 120 may be an SiO2 layer. The insulating layer 111 and the capping layer 120 may be etched in a different etching condition as shown in Table 1, but the etching of the insulating layer 111 and the capping layer 120 can be performed under the same etching conditions if the etching rate of the insulating layer 111 and the capping layer 120 is different.

TABLE I

| | Pressure | Power 1 | Power 2 | SF6 | O2 | He | Time |
|---|---|---|---|---|---|---|---|
| Layer | (mTorr) | (W) | (W) | (sccm) | (sccm) | (sccm) | (sec) |
| Capping | 40 | 1500 | 500 | 100 | 50 | | 70 |
| layer | | | | | | | |
| In- | 200 | 600 | | 150 | 80 | 350 | 70 |
| sulating | | | | | | | |
| layer | | | | | | | |

The photoresist layer pattern 124 may be consumed during the etching processes, so the distance of the photo resist pattern 123 ‘d’ in FIG. 4A may be larger than that of the capping layer pattern 122 ‘e’ in FIG. 4A after the etching process, as can be seen in FIG. 4B. The distances ‘d’ and ‘e’ are taken in a direction substantially parallel with a plane of the substrate 100, and substantially in a horizontal direction as illustrated in FIG. 4A. Due to the different etching rate between the insulating layer 111 and the capping layer 120, a protrusion region 121 of the capping layer 120 is formed above the insulating layer pattern 112.

Referring to FIG. 4B, a cross-sectional view of an actual TFT LCD array panel during a method of fabricating a metal line is shown at a stage before the photoresist layer pattern 123 is removed. In exemplary embodiments, a taper angle of the insulating layer pattern 112 ‘theta’ (See, FIG. 4A) may be higher or lower than 90 degrees.

Referring to FIG. 5, a low-resistive conductive layer pattern 130 is formed on the seed layer pattern 110. The low-resistive conductive layer pattern 130 is formed by the electroless plating method. In one exemplary embodiment where the seed layer pattern 110 is formed of molybdenum (Mo), the low-resistive conductive layer pattern 130 may be formed by first immersing the surface of the seed layer pattern 110 in a plating solution containing a metal salt such as a palladium (Pd) salt, a platinum (Pt) salt, or a gold (Au) salt, so that the surface of the seed layer pattern 110 can be plated with the metal salt.

The metal salt-plated seed layer pattern 110 is immersed in a plating solution containing the low-resistive metallic material 130 so that a reduction process is caused by the metal salt on the seed layer pattern 110. As a result of the reduction process, the low-resistive conductive layer pattern 130 is formed only on the surface of the seed layer pattern 110. The low-resistive conductive layer pattern 130 may include copper (Cu), aluminum (Al), gold (Au), silver (Ag), or an alloy thereof. In one exemplary embodiment, it is preferred that the low-resistive conductive layer pattern 130 includes copper (Cu) or a copper alloy. The low-resistive conductive layer pattern 130 may be formed to a thickness of about 5,000 Å to about 50,000 Å.

In an exemplary embodiment, the thickness of the insulating layer 111 may be about 5,000 Å to about 50,000 Å, and the thickness of the capping layer 120 may be about 100 Å to about 5000 Å, as previously described. If the low-resistive conductive layer pattern 130 should be thicker than 50,000 ÅÅ, the thickness of the insulating layer 111 may be increased to greater than about 50,000 Å. A thickness ratio of the insulating layer 111 to the capping layer 120 is approximately 0.01 to 0.2.

Referring again to FIG. 5, a length of the protrusion region 121 ‘f’ is greater than about 0.5 micrometer (μm), and the distance between the adjacent protrusion regions 121 ‘e’ is greater than 0.5 micrometer (μm), so as to facilitate the formation of the low-resistive conductive layer pattern 130 by the electroless plating method. As the low-resistive conductive layer pattern 130 is grown upwards, it will be in contact with the bottom (e.g., lower) surface of the protrusion region 121.

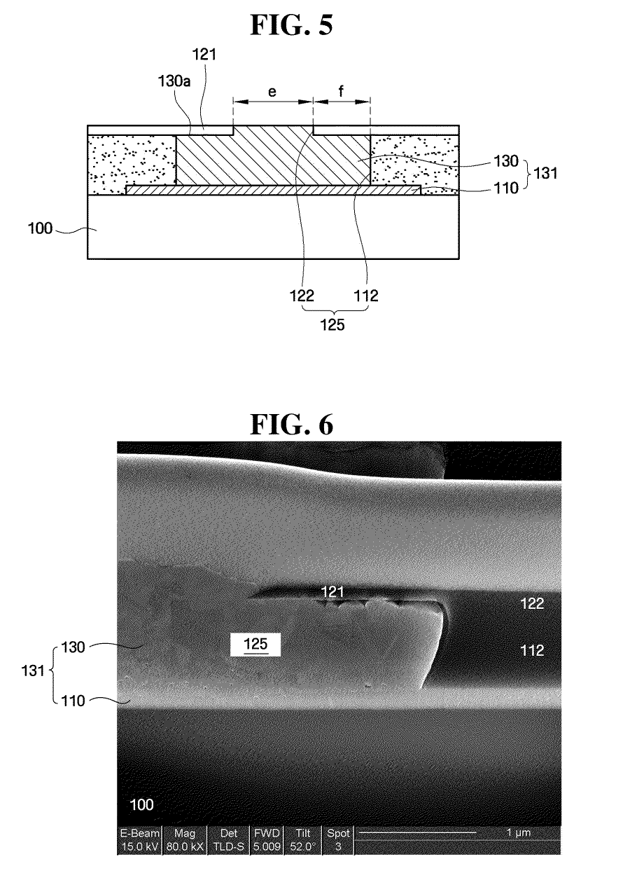

Referring to FIG. 6, a cross-sectional view of an actual TFT LCD array panel during a method of fabricating a metal line. The low-resistive conductive layer pattern 130 is formed on the seed layer pattern 110, and the protrusion region 121 suppresses a part of the low-resistive conductive layer pattern 130. A portion of the low-resistive conductive layer pattern 130 which is not covered (e.g., overlapped) by the protrusion region 121 can be grown to the same height of an upper surface of the capping layer pattern 122. The low-resistive conductive layer pattern 130 is fully buried in the trench 125 which includes the insulating layer pattern 112 and the capping layer pattern 122. In an exemplary embodiment, an upper surface of the low-resistive conductive layer pattern 130 includes a first portion coplanar with the upper surface of the capping layer pattern 122, and a second portion coplanar with a lower surface of the capping layer pattern 122, such as illustrated in FIGS. 1 and 5.

The low-resistive conductive layer pattern 130 under the protrusion region 121 is no longer grown because the protrusion region 121 prohibits (e.g., suppresses) a portion of a surface of the low-resistive conductive layer pattern 130 from contacting the plating solution. Moreover, since the protrusion region 121 suppresses that portion of the surface of the low-resistive conductive layer pattern 130, adhesion of the low-resistive conductive layer pattern 130 to the seed layer pattern 110 and/or the insulating substrate 100 is promoted and made relatively easy.

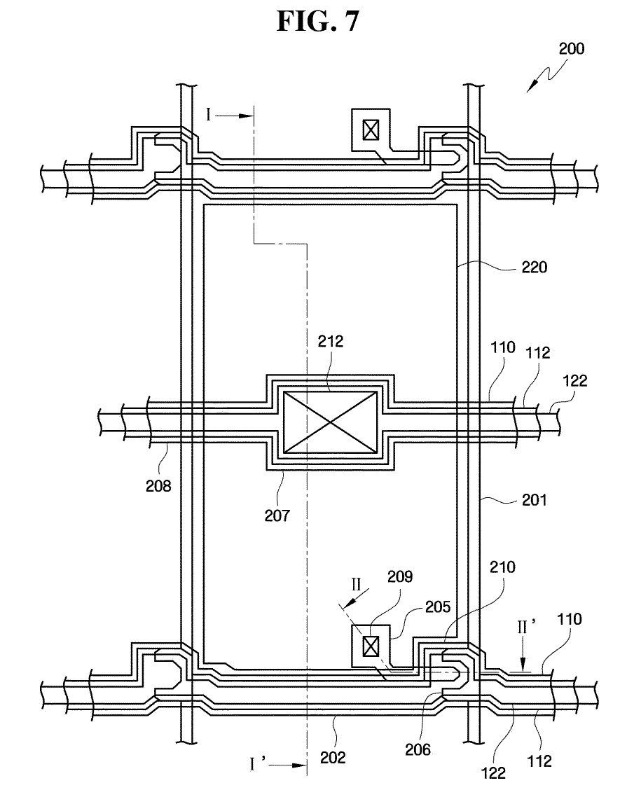

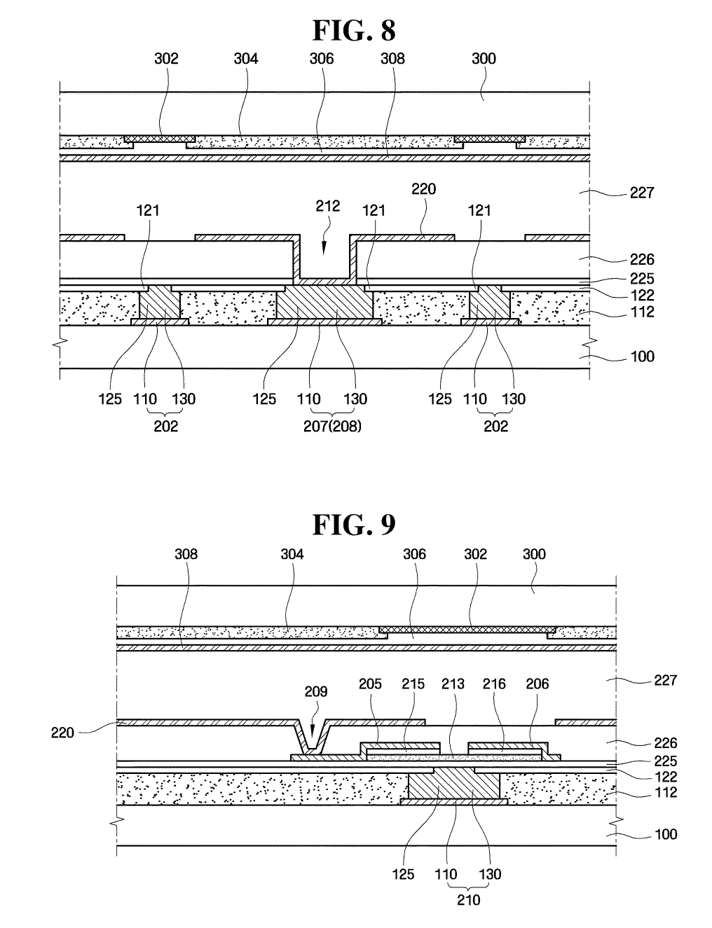

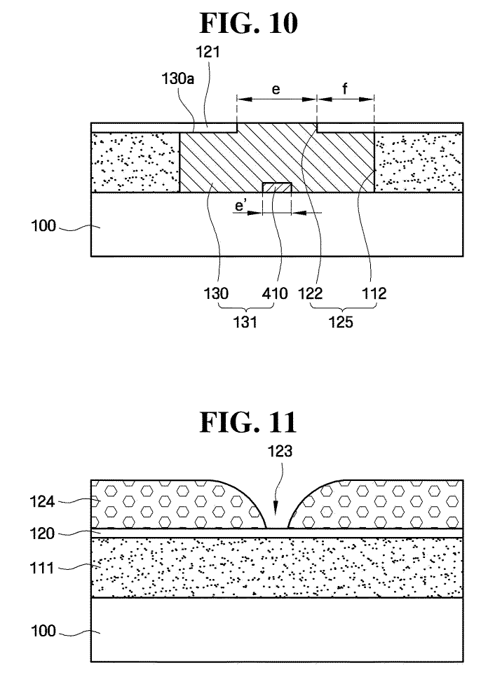

FIG. 7 is a plan view of an exemplary embodiment a thin film transistor (“TFT”) liquid crystal display (“LCD”) panel 200 according to the present invention, and FIG. 8 and FIG. 9 are sectional views of the TFT array panel 200 shown in FIG. 7 taken along line I-I′ and II-II′, respectively.

Referring to FIG. 7, a plurality of gate lines 202 and a plurality of storage lines 208 are formed on an insulating substrate 100. The insulating substrate 100 may include a material such as transparent glass or plastic. In exemplary embodiments, the gate lines 202 and the storage lines 208 may be formed using an electroless plating method. The gate lines 202 transmit gate signals and extend substantially in a transverse direction. Each of the gate lines 202 includes a plurality of gate electrodes 210 projecting upward (e.g., in the plan view of FIG. 7), and a gate pad (not shown) having a relatively large area for contact with another layer or an external driving circuit (not shown). Each of the storage lines 208 is substantially parallel to the gate lines 202 and includes a storage electrode 207 branched from the storage line 208. A storage electrode 207 may be supplied with a predetermined voltage.

Referring to FIG. 8, the gate lines 202 and storage lines 208 include two conductive films, e.g., a seed layer pattern 110 and an low-resistive conductive layer pattern 130 disposed thereon, which have different physical characteristics. The low-resistive conductive layer 130 may be made of low resistivity metal including, but not limited to, a Cu-containing metal such as Cu and a Cu alloy for reducing signal delay or voltage drop. The seed layer pattern 110 may be made of a material including, but not limited to, molybdenum (Mo), aluminum (Al), chromium (Cr), nickel (Ni), copper (Cu), titanium (Ti), tantalum (Ta), and tungsten (W) or an alloy thereof, which has relatively good adhesive properties with other materials such as the low-resistive conductive material 130 or the insulating substrate 100.

The gate lines 202 and the storage lines 208 are buried in a trench 125 (See, FIG. 1), and a protrusion region 121, which includes a capping layer pattern 122, covers a part of the gate lines 202. A top surface of the gate lines 202 which are not covered by the protrusion region 121 may be grown to be disposed at a substantially same height of a top surface of the capping layer pattern 122 and/or the protrusion region 121, such as by using an electroless plating method.

Since the gate lines 202 are buried in the trench 125, and since the top surface of the gate lines 202 are disposed at a substantially same height of the top surface of the capping layer pattern 122 and/or the protrusion region 121, disadvantages associated with step differences (e.g., height differences) between the gate lines 202 and other layers or substrates are reduced or effectively eliminated. Moreover, since the protrusion region 121 suppresses part of the surface of the low-resistive conductive layer pattern 130 to secure the low-resistive conductive layer pattern 130 in the TFT LCD panel 200, the adhesive strength of low-resistive conductive layer pattern 130 to the seed layer pattern 110 is advantageously improved.

Referring to FIG. 9, a plurality of semiconductor layer patterns 213 preferably made of hydrogenated amorphous silicon (abbreviated to “a-Si”) or polysilicon are formed on a gate insulating layer 225. A plurality of ohmic contact layer patterns 215, 216 is formed directly on the semiconductor layer pattern 213. In an exemplary embodiment, the ohmic contact layer patterns 215, 216 are preferably made of hydrogenated a-Si heavily doped with an n-type impurity such as phosphorous, or they may be made of silicide.

A plurality of data lines 201, a plurality of drain electrodes 205, and a plurality of pixel electrodes 220 are physically or electrically connected to each other. The data lines 201 transmit data signals and extend substantially in the longitudinal direction to intersect the gate lines 202. Each of the data lines 201 also intersects the storage lines 208 and runs between adjacent pairs of storage electrodes 207.

Each data line 201 includes a plurality of source electrodes 206 projecting toward the gate electrodes 210 and curved like the letter J, and an end portion having a data pad (not shown) for contact with another layer or an external driving circuit (not shown). Drain electrodes 205 are separated from the data lines 201 and disposed opposite the source electrodes 206 with respect to the gate electrodes 210. Each of the drain electrodes 205 includes a relatively wide end portion and a relatively narrow end portion. The narrow end portion is partly enclosed by the source electrode 206. A passivation layer 226 is formed on the data lines 201, the drain electrodes 205, the interconnection members, and the exposed portions of the semiconductor layer pattern 213.

Referring to FIGS. 8 and 9, a passivation layer 226 may be made of an inorganic insulator or an organic insulator. The passivation layer 226 may have a substantially flat (e.g. planar) top surface. The inorganic insulator may include, but is not limited to, silicon nitride and silicon oxide layer. The organic insulator may have photosensitivity and/or a dielectric constant of less than about 4.0.

In exemplary embodiments, the passivation layer 226 may include a lower film of an inorganic insulator, and an upper film of an organic insulator, such that the passivation layer 226 has the excellent insulating characteristics of the organic insulator while preventing the exposed portions of the semiconductor layer pattern 213 from being damaged by the organic insulator. The upper layer including the organic insulator may have a substantially flat surface to induce the passivation layer 226 to have a flat top surface.

Referring again to FIGS. 8 and 9, the passivation layer 226 may include a plurality of contact holes. Pixel electrodes 220 are directly connected to the drain electrodes 205. The pixel electrodes 220 may include a transparent conductive material, such as a-ITO, ITO, and IZO.

An opposing insulating substrate 300 may include transparent insulating material, such as glass. A black matrix 302 preventing light leakage and color filters 304 arranged at least on a pixel region are formed on the opposing insulating substrate 300. An overcoat layer 306 is formed on the color filters 304, and a common electrode 308 including transparent conductive material such as ITO or IZO is formed on the overcoat layer 306

The pixel electrodes 220 supplied with the data voltages generate electric fields in cooperation with the common electrode 308 supplied with a common voltage, which determine the orientations of liquid crystal molecules of a liquid crystal layer 227 disposed between the two electrodes.

Referring to FIG. 8, the pixel electrode 220 and the common electrode 308 form a capacitor referred to as a “liquid crystal capacitor,” which stores applied voltages after the TFT is turned off. The pixel electrode 220 overlaps the storage electrode line 208 including storage electrodes 207. The pixel electrode 220 and the storage line 208 forms an additional capacitor referred to as a “storage capacitor,” which enhances the voltage storing capacity of the liquid crystal capacitor.

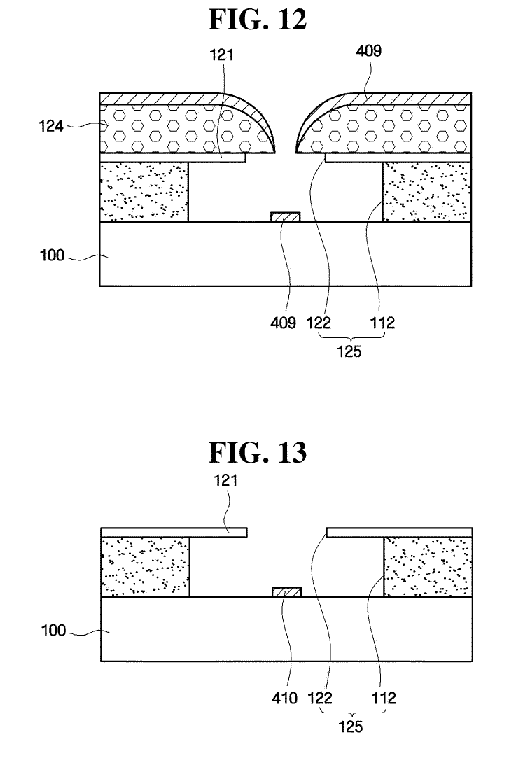

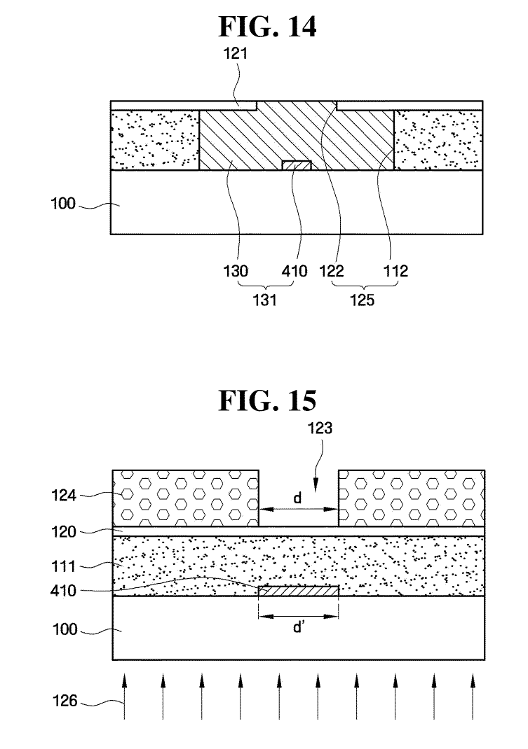

FIG. 10, FIG. 11, FIG. 12, FIG. 13, and FIG. 14 illustrate other exemplary embodiments of the present invention.

Referring to FIG. 10, a seed layer pattern 410 is formed on an insulating substrate 100, and a low-resistive conductive layer pattern 130 is formed on the seed layer pattern 410 and also on the insulating substrate 100 which is not covered by the seed layer pattern 410 in a trench 125. In an exemplary embodiment, the low-resistive conductive layer pattern 130 is formed by an electroless plating method in the trench 125.

The trench 125 includes an insulating layer pattern 112 and a capping layer pattern 122. The capping layer pattern 122 includes a protrusion region 121. The protrusion region 121 covers (e.g., overlaps) part of the low-resistive conductive layer pattern 130. Advantageously, the adhesive strength of the low-resistive conductive layer pattern 130 to the seed layer pattern 410 and the insulating substrate 100 is increased due to the suppression of the protrusion region 121 on the low-resistive conductive layer pattern 130.

In FIG. 10, the low-resistive conductive layer pattern 130 directly contacts the substrate 100, unlike in FIG. 1 where the low-resistive conductive layer pattern 130 is separated from the substrate 100 by the seed layer pattern 110. In FIG. 10, the low-resistive conductive layer pattern 130 directly contacts all of the capping layer pattern 122, the insulating layer 112, the seed layer pattern 410 and the substrate 100. In contrast, the low-resistive conductive layer pattern 130 in FIG. 1 contacts only the capping layer pattern 122, the insulating layer 112, and the seed layer pattern 110.

In FIG. 10, a first portion of an upper surface of the low-resistive conductive layer pattern 130 is coplanar with an upper surface of the capping layer pattern 122 including the protrusion region 121. A second portion of the upper surface of the low-resistive conductive layer pattern 130 is not coplanar with the first portion, and is closer to the substrate 100 than the first portion. The second portion of the upper surface of the low-resistive conductive layer pattern 130 is coplanar with a lower surface of the protrusion region 121, and directly contacts the capping layer pattern 122. As discussed above, since the low-resistive conductive layer pattern 130 directly contact both the protrusion region 121 and the substrate 100 while being held between the protrusion region 121 and the substrate 100, the adhesive strength of the low-resistive conductive layer pattern 130 to the seed layer pattern 410 and the insulating substrate 100 is advantageously increased

A width of the capping layer pattern 122 ‘e’ is wider than 0.5 μm, and a length of the protrusion region 121 ‘f’ is longer than 0.5 μm. A width of the seed layer pattern 410 ‘e′’ is substantially the same as or smaller than a width of the capping layer pattern 122 ‘e’. Alternatively, the width of the seed layer pattern 410 is slightly wider or narrower than that of the capping layer pattern 122 due to process conditions such as a photoresist developing condition, an etching condition of an insulating layer pattern 112 or a capping layer pattern 122, or other thin film process conditions. The distances ‘d’ and ‘e’ are taken in a direction substantially parallel with a plane of the substrate 100, and substantially in a horizontal direction as illustrated in FIG. 4A.

Referring to FIG. 11 to FIG. 14, another exemplary embodiment of a fabrication of a metal line according to the present invention is shown.

Referring to FIG. 11, an insulating layer 111 and a capping layer 120 are deposited on the insulating substrate 100. A photoresist layer pattern 123 is formed on the capping layer 120. A detailed procedure for the formation of the photoresist layer pattern 123 was previously described, and further description will be omitted.

Referring to FIG. 12, the capping layer 120 and the insulating layer 111 are etched off using the photoresist layer pattern 123 as an etching mask. The etching is performed by a wet or dry etching method. An insulating layer pattern 112 and a capping layer pattern 122 are formed on the insulating substrate. A trench 125 includes the capping layer pattern 122 and the insulating layer pattern 112. A seed layer 409 is deposited both on the photoresist layer 124 and the insulating substrate 100 in the trench 125, such as by using a sputtering or an evaporation method.

Referring to FIG. 13, because the seed layer 409 on the photoresist layer 124 is separated from the capping layer pattern 122 while the photoresist layer 124 is removed from the capping layer pattern 122, both the seed layer 409 on the photoresist layer 124 and the photoresist layer 124 are removed, such as by a stripper at substantially the same time. The seed layer pattern 410 is formed in the trench 125 on the insulating substrate 100.

Referring to FIG. 14, a low-resistive conductive layer pattern 130 is initially grown only on the seed layer pattern 410 in the trench 125. As the low-resistive conductive layer pattern 130 grows, the low-resistive conductive layer pattern 130 also grows on the insulating substrate which is not covered by the seed layer pattern in the trench 125, such that the low-resistive conductive layer pattern 130 is disposed directly contacting the substrate 100. Once the entire bottom side of the trench 125 is filled with the low-resistive conductive layer pattern 130, the low-resistive conductive layer patter 130 grows up (e.g., vertically as shown in FIG. 14) to the capping layer pattern 122, such that the low-resistive conductive layer pattern 130 also directly contacts the capping layer pattern 122.

The trench 125 may be considered as completely filled with the low-resistive conductive layer pattern 130. The trench 125 may be referred to as being solely defined collectively by outer surfaces of the seed layer pattern 410, an upper surface of the substrate 100, inner surfaces of the insulating pattern 112, inner surfaces of the capping layer pattern 122 and a plane that is coextensive with an upper surface of the capping layer pattern 122. The low-resistive conductive layer pattern 130 is in contact with both the insulating substrate 100 and a bottom surface of the protrusion region 121. Advantageously, the protrusion region 121 suppresses the low-resistive conductive layer pattern 130, and reduces or effectively prevents separating of the low-resistive conductive layer pattern 130 from the insulating substrate 100.

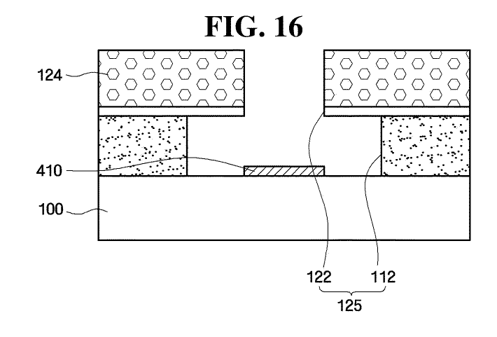

FIG. 15 shows still another exemplary embodiment of the present invention. A seed layer pattern 410 is formed on an insulating substrate 100. An insulating layer 111 and a capping layer 120 are deposited on the seed layer pattern 410. A negative photoresist layer 124 is formed on the capping layer 120. The negative photoresist layer 124 is exposed to, for example, ultraviolet light (126) from a bottom side of the insulating substrate 100 using the seed layer pattern 410 as an optical mask. The negative photoresist layer 124 which is not exposed is removed during a developing process. The negative photoresist layer 124 which is exposed is not removed during the developing process. A width of a negative photoresist layer pattern 123 ‘d’ is substantially the same width of the seed layer pattern 410 ‘d′’.

Referring to FIG. 16, the capping layer 120 and the insulating layer 111 are etched off, and an insulating layer pattern 112 and a capping layer pattern 122 are formed on the insulating substrate 100. The negative photoresist layer pattern 123 may be removed (not shown). In the illustrated exemplary embodiment of the present invention, since a negative photoresist layer pattern 123 is formed using the seed layer pattern 410 as an optical photo mask, process steps can be advantageously reduced.

What is claimed is:

1. A metal line substrate, comprising;
an insulating substrate;
an insulating layer pattern disposed on the insulating substrate;
a capping layer pattern disposed on the insulating layer pattern, and the capping layer pattern comprising a protrusion region;
a trench defined by the insulating layer pattern and the capping layer pattern;
a seed layer pattern disposed on the insulating substrate;
a low-resistive conductive layer pattern disposed in the trench and contacting the seed layer pattern;
wherein the protrusion region contacts the low-resistive conductive layer pattern.

2. The metal line substrate of claim 1, wherein the protrusion region comprises a bottom surface contacting the low-resistive conductive layer pattern.

3. The metal line substrate of claim 2, wherein a top portion of the low-resistive conductive layer pattern is coplanar with a top surface of the capping layer pattern.

4. The metal line substrate of claim 3, wherein a width of the capping layer pattern is greater than 0.5 micrometer (μm).

5. The metal line substrate of claim 4, wherein a length between the protrusion region and an adjacent protrusion region is greater than 0.5 micrometer (μm).

6. The metal line substrate of claim 1, wherein the capping layer comprises at least one of SiOx, SiNx and SiONx.

7. The metal line substrate of claim 1, wherein a thickness of the capping layer pattern is about 100 Å to about 5,000 Å.

8. The metal line substrate of claim 1, wherein a thickness of insulating layer pattern is about 5,000 Å to about 50,000 Å.

9. The metal line substrate of claim 8, wherein the low-resistive conductive layer pattern is directly in contact with the seed layer pattern.

10. The metal line substrate of claim 9, wherein the low-resistive conductive layer pattern comprises at least one of copper and copper alloy.

11. The metal line substrate of claim 10, wherein the low-resistive conductive layer pattern is directly in contact with the insulating substrate.

12. The metal line substrate of claim 11, wherein a width of the seed layer pattern is substantially the same with as a width of the capping layer pattern, or smaller than that of the capping layer pattern.

13. The metal line substrate of claim 12, wherein the seed layer pattern comprises at least one of molybdenum (Mo), aluminum (Al), chromium (Cr), nickel (Ni), copper (Cu), titanium (Ti), tantalum (Ta), and tungsten (W) and an alloy thereof.

14. The metal line substrate of claim 13, wherein a thickness of the seed layer pattern is about 100 Å to about 5,000 Å.

15. The metal line substrate of claim 1, wherein a length of the protrusion region is greater than 0.5 micrometer (μm).

16. A method of manufacturing a metal line substrate, the method comprising:
preparing an insulating substrate;
forming a seed layer pattern on the insulating substrate;
forming an insulating layer pattern on the seed layer pattern;
forming a capping layer pattern on the insulating substrate and on the capping layer pattern comprising a protrusion region;
defining a trench region by the insulating layer pattern and the capping layer pattern;
forming a low-resistive conductive layer pattern in the trench region and above the seed layer pattern;
wherein the protrusion region contacts the low-resistive conductive layer pattern.

17. The method of claim 16, wherein the protrusion region comprises a bottom surface contacting the low-resistive conductive layer pattern.

18. The method of claim 17, wherein the preparing an insulating substrate includes:
forming a seed layer on a photoresist layer pattern used in forming the seed layer pattern; and
removing the seed layer on the photoresist layer pattern.

19. The method of claim 18, wherein a width of the seed layer pattern is substantially the same or less than a width of the capping layer pattern.

20. The method of claim 17, wherein the forming a low-resistive conductive layer pattern including an electroless plating process forming the low-resistive conductive layer pattern.

21. The method of claim 16, wherein the defining a trench region includes forming a photoresist layer pattern used in forming the trench region, the forming the photoresist layer includes a back side exposure process using the seed layer pattern as an optical mask.

22. A thin film transistor (“TFT”) substrate, comprising;
an insulating substrate;
a gate line and a data line disposed on the insulating substrate;
an insulating layer pattern and a capping layer pattern; and
a trench defined by the insulating layer and the capping layer pattern disposed on the insulating substrate;
wherein the capping layer pattern includes a protrusion region contacting the gate line or the data line disposed in the trench.

23. The thin film transistor (“TFT”) substrate of claim 22, wherein the gate line or data line further comprises a low-resistive conductive layer pattern and a seed layer pattern.

24. The thin film transistor (“TFT”) substrate of claim 23, wherein the protrusion region comprises a bottom surface contacting the low-resistive conductive layer pattern.
